(19) United States
(12) Patent Application Publication
(10) Pub. No.: US 2009/0001999 A1
(43) Pub. Date: Jan. 1, 2009

(54) Proximity Sensor with Connection Hole, and Method for Manufacturing the Same

(76) Inventor: Malcolm F. Douglas, Wales (GB)

Correspondence Address: 3M INNOVATIVE PROPERTIES COMPANY, PO BOX 33427, ST. PAUL, MN, 55133-3427, US

(21) Appl. No.: 12/160,633

(22) PCT Filed: Jan. 19, 2007
(86) PCT No.: PCT/US07/01395

§ 371 Date: Jul. 11, 2008

(30) Foreign Application Priority Data
Jan. 19, 2006 (EP) 06001149.1

(51) Int. Cl. G01R 27/08; H01G 9/00

(52) U.S. Cl. 324/688; 29/25.03

(57) ABSTRACT

The present disclosure relates to a capacitive sensor film (50) for mounting to a body, said film comprising a backing layer (2) having, on one side, a rear major surface (2a) facing, in use, the body and, on the other side, a front major surface (2b), said rear major surface (2a) bearing a guard conductor (1) and said front major surface (2b) bearing a sensor conductor (7), and at least on through-going hole (10) extending through the backing layer to enable electrical contact to be made to one of the conductors from the respectively opposite side of the film, wherein the inner wall of the through-going hole is covered, at least partly, by an electrically-insulating film (11).

### FIELD

The present disclosure relates to a capacitive sensor film for mounting to a body, for example to detect the presence of an external object. The present disclosure also relates to an improved method for manufacturing such capacitive sensor films.

### BACKGROUND

Capacitive proximity sensors have been used in various industrial applications for locating the presence of objects or materials. Various forms of capacitive proximity sensors are known and are suitable for use in different environments and applications including, for example, touch-operated systems, collision-prevention systems, occupancy-detection systems, and security/warning systems. In one field of application, capacitive proximity sensors have been fitted, for example, with the rear side and/or bumpers of cars. When the vehicle is reversed a warning signal is provided when the car approaches an object so that a collision can be safely avoided while still allowing the driver to conveniently position the car close to such object.

GB 2,400,666 discloses a capacitive proximity sensor comprising a substrate bearing two metal plates on its opposite major surfaces. The capacitive proximity sensor can be provided inside the bumper of a vehicle. The metal plate facing outwardly is referred to as the sensor conductor whereas the metal plate facing the car body is called the guard conductor. The sensor conductor is screen-printed with conductive ink onto the substrate whereas the guard conductor may be a metal strip. The guard conductor is typically larger than the sensor conductor and provides a shield between the sensor conductor and the car body. The change of the capacitance between the sensor conductor and ground is monitored and provides an indication for the distance between the car and the object.

Controlling devices for capacitive sensors are disclosed, for example, in GB 2,396,015 and in WO 02/19,524.

GB 2,374,422 addresses the problem of reducing the sensitivity of a capacitive proximity sensor to very close objects that the sensor is not required to detect. Specifically, in the case of a sensor on a vehicle bumper, GB 2,374,422 addresses the problem of reducing the effect of the presence of water as caused, for example, by steady rain. In one embodiment it is suggested to arrange an extra conductive plate on the major side of the substrate bearing the sensor conductor. The extra conductive plate, which can be arranged on the sensor conductor side above or below said sensor conductor or both (with respect to the level of the street), is often referred to as superguard conductor. In operation, an amplified guard signal is applied to the superguard conductor which has the effect of making the guard appear bigger. The superguard conductor is effective in attenuating or minimizing capacitance changes resulting from drips of water running across the front of the sensor. A capacitive proximity sensor comprising a superguard conductor is also disclosed in GB 2,404,443.

GB 2,348,505 discloses a sensor conductor geometry where the end regions of such conductor may be wider than its central position. This tends to improve the sensitivity of the capacitive proximity sensor at the corners of the vehicle.

GB 2,386,958 discloses an integral capacitive sensor for proximity detection which is integrally moulded into either the back face or the middle of the bumper of a car.

U.S. Pat. No. 5,801,340 discloses a capacitive sensor for detecting the pressure of an object in a sensing region which has a relatively complicated construction and comprises, in the sequence given, a conductive ground plate, an insulator, a conductivity guard layer, an insulator and a conductive touch or sensing plate followed by another insulator.

US 2002/0,158,582 discloses a capacitive sensor for automotive applications comprising an essentially non-conductive protective screen, an electrically insulating film situated behind said protective screen and having two faces each of which is coated at least in part with an electrically conductive material.

The capacitive sensors discussed so far do not meet all practical requirements to a sufficient degree. Electrical contact is typically made to the conductor plates on the opposite surfaces of the substrate from both sides of the capacitive sensor device which renders the incorporation of the sensor device in the desired location, for example into the bumper of a car, more complicated and adversely affects the reliability of the sensor device during its lifetime. The methods of manufacturing capacitive proximity sensors disclosed in the prior art include, for example, screen-printing or coating of the conductor plates which is expensive and hence does not meet the requirements of mass production. Other conventional capacitive proximity sensor constructions require a mechanical anchoring which may add costs and is less desirable from a processing point of view.

Accordingly, in some embodiments, the present disclosure provides a capacitive proximity sensor device which does not exhibit the shortcomings of the state-of-the-art devices or exhibits them to a lower degree only. In some embodiments, the present disclosure provides a capacitive sensor device which can be electrically contacted easily and reliably. In some embodiments, the present disclosure provides a method of manufacturing capacitive proximity sensors which is improved in comparison to state-of-the-art methods and complies with the requirements of mass production. Other features and advantages of various embodiments of the present disclosure can readily be taken from the following detailed description.

### SUMMARY

The present disclosure relates to a capacitive sensor film for mounting to a body, said film comprising a backing layer having, on one side, a rear major surface facing, in use, the body and, on the other side, a front major surface, said rear major surface bearing a guard conductor and said front major surface bearing a sensor conductor, and at least on through-going hole extending through the backing layer to enable electrical contact to be made to one of the conductors from the respectively opposite side of the film, wherein the inner wall of the through-going hole is covered, at least partly, by an electrically-insulating film.

The present disclosure furthermore relates to a method comprising
(i) providing a backing layer comprising a rear major surface and a front major surface,
(ii) applying a guard conductor to the rear major surface of the backing layer,
(iii) applying a sensor conductor to the front major surface of the backing layer,
(iv) providing one or more through-going hole or holes extending through the backing layer so that the guard conductor, the sensor conductor and optionally the superguard conductor can be electrically contacted from one major surface of the laminate.

The present disclosure furthermore relates more particularly, but not exclusively, to the use of the capacitive sensor film of the present disclosure for automotive applications.

### BRIEF DESCRIPTION OF THE FIGURES

FIG. 1 shows a top view of the front major surface of the backing layer 2 of a precursor of a capacitive sensor film 50 of one embodiment of the present disclosure.

FIG. 2 shows a cross-sectional view of the precursor film of FIG. 1 along line A-A indicated in FIG. 1.

FIG. 3 is a top view the cross-sectional view of the capacitive sensor film 50 comprising two through-going holes 10.

FIG. 4 is a top view of the capacitive sensor film of FIG. 3 additionally comprising an electrically insulating film 11 covering the through-going holes 10.

FIG. 5 is a top view of the capacitive sensor film 50 of FIG. 4 comprising two additional auxiliary conductors 12, 13 being electrically connected to the sensor conductor 7 and the superguard conductor 5, respectively, and extending into the area of said through-going holes.

FIG. 6 is a cross-sectional view of the capacitive sensor film 50 of FIG. 5 along line B-B indicated in FIG. 5.

FIG. 7 is the cross-sectional view of the capacitive sensor film 50 of FIG. 5 additionally comprising two protective layers 16 and 17.

FIG. 8 is the cross-sectional view of the capacitive sensor film of FIG. 5 with a socket 31 being applied to the rear major surface 51 of the film 50.

### DETAILED DESCRIPTION

The term “film” as used above and below refers to an article having an extension in two directions which exceeds the extension in a third direction which is essential normal to said two directions by a factor of at least 5 and more preferably by at least 10. More generally, the term “film” is used herein to refer to a flexible sheet-like material, and includes sheetings, foils, strips, laminates, ribbons and the like. The term electrically isolating as used above and below refers to materials having a specific bulk resistivity as measured according to ASTM D 257 of at least 1×10̂12 Ohm·centimeters (Ωcm) and more preferably of at least 1×10̂13 Ωcm. The term electrically conductive as used above and below refers to materials having a surface resistivity as measured according to ASTM B193-01 of less than 1 Ohms/square centimeter (Ω/cm²).

Generally, the capacitive sensor film 50 comprises an electrically isolating backing layer 2 bearing on one of its major surfaces a guard conductor 1 and on its opposite major surface a sensor conductor 7.

The backing layer is preferably continuous and preferably has a thickness of between 20-500 micrometers (μm), in some embodiments, between 25-350 μm and in some embodiments, between 25-150 μm. Suitable backing materials include, e.g., polymeric films and layers, paper films and layers, layers of non-wovens, laminates (such as, for example, polyacrylate foams laminated on both sides with polyolefin films, and papers laminated or jig-welded with polyethylene terephthalate) and combinations thereof. Useful polymeric films and layers include, for example, polyolefin polymers, monoaxially oriented polypropylene (MOPP), biaxially oriented polypropylene (BOPP), simultaneously biaxially oriented polypropylene (SBOPP), polyethylene, copolymers of polypropylene and polyethylene, polyvinylchloride, copolymers having a predominant olefin monomer which may be optionally chlorinated or fluorinated, polyester polymers, polycarbonate polymers, polymethacrylate polymers, cellulose acetate, polyester (e.g. biaxially oriented polyethylene terephthalate), vinyl acetates, and combinations thereof. Useful backings also include surface modified backings modified by, e.g., plasma discharge techniques including corona discharge treatment and flame treatment, mechanical roughening and chemical primers.

The guard conductor 1 comprises an electrically conductive material and, in some embodiments, one or more metals which are applied as a layer or a film to one of the major surfaces of the backing layer 2. In some embodiments, the guard conductor 1 comprises an aluminium layer. The guard conductor may be formed, for example, by a metal film which is bonded to such major surface of the hacking layer 2 with an adhesive layer 3 such as, for example, a pressure-sensitive adhesive layer. The guard conductor 1 may also be directly applied to such major surface of the backing layer 2, for example, by vacuum metal vapour deposition.

The thickness of the guard conductor 1 may vary widely depending on the method of manufacturing it. A guard conductor layer 1 obtained by vacuum metal vapour deposition may be as thin as 200-800 Angstroms (Å) and in some embodiments, 300-500 Å. When using an aluminum foil as a guard layer 1 it may preferably have a thickness of from 1-100 μm, in some embodiments, 2-50 μm and in some embodiments, 3-30 μm.

The guard conductor 1 acts as a shield to reduce the sensitivity of the sensor conductor 7 to anything behind it in the direction of the body. In automotive applications, for example, it is desirable that the sensor conductor 7 detects objects that are generally outward of the vehicle but is effectively blind towards the inside of the vehicle.

Therefore the dimensions of the guard conductor 1 are preferably chosen to match at least those of the sensor conductor 7 but in some embodiments, the dimensions of the guard conductor 1 exceed at least partly those of the sensor conductor.

In some embodiments the guard conductor 1 essentially fully covers the major side of the backing layer 2 it is attached to.

The sensor conductor 7 is arranged on the major surface of the backing 2 which is opposite to the major surface being the guard conductor 1.

The sensor conductor 7 comprises an electrically conductive material and, in some embodiments, one or more metals. In some embodiments the sensor conductor 7 comprises a relatively cheap material such as an aluminium layer which may be applied by vacuum metal vapour deposition or as an aluminium film or foil which can be bonded to the backing 2, for example, by an adhesive layer such as, for example, a pressure-sensitive adhesive layer. In another embodiment the sensor conductor 7 comprises a copper layer or plated copper layer as a conductive material which may be used, for example, in the form of optionally flattened wires which are applied to the backing layer, for example, by an adhesive layer 9. The sensor conductor may also comprise a copper layer which can be applied, for example, by vacuum metal vapour deposition or as an adhesively bonded copper film or foil.

The sensor conductor 7 may assume a variety of shapes and may exhibit a continuous or discontinuous configuration, respectively.

In automotive applications where the capacitive sensor film is attached, for example, to the rear side of a car, the sensor conductor may have the form of an elongated strip. In GB 2,348,505 it is disclosed that the sensor conductor 7 may be a strip comprising lobes at its two end regions in the longitudinal direction, i.e., the sensor conductor is wider at its end regions in the longitudinal direction than in its central portion. In use, the lobes are positioned at the ends of the bumper at the edges of a vehicle to provide a more uniform sensitivity profile along the width of the car.

In some embodiments the sensor 7 conductor comprises a sequence of strips essentially extending in a longitudinal direction (i.e., for example, essentially along and parallel to the length of the backing layer 2). The strips may be formed by optionally flattened metal wires or strips of a metal foil. If the strips are arranged essentially parallel to each other, another strip may be provided in a transverse direction to electrically connect the wires arranged in the longitudinal direction.

Sensor conductors 7 comprising a discontinuous arrangement of conductive areas such as an arrangement of optionally flattened wires whereby those areas are electrically connected, exhibit an especially advantageous sensitivity and may be preferred.

The thickness of the sensor conductor 7 may vary widely depending on the method of manufacturing it. Sensor conductors comprising optionally flattened metal wires exhibit a thickness of typically between 20 and 200 μm and, in some embodiments, of between 25 and 100 μm. Sensor conductors 7 obtained by vacuum metal vapour deposition may be as thin as 200-800 Å and, in some embodiments, 300-500 Å. When using an aluminum foil as a sensor layer 7 it may have a thickness of from 1-100 μm, in some embodiments, 2-50 μm and in some embodiments, 3-30 μm.

The capacitive sensor film 50 of the present disclosure may additionally comprise a superguard conductor 5 which may be arranged on the surface of the backing 2 bearing the sensor conductor 7. The superguard conductor is provided to reduce the sensitivity of the sensor conductor 7 to the presence of very close objects that the sensor conductor is not required to detect. In automotive applications the superguard conductor 5 may be arranged—relative to the road level—above or below the sensor conductor. In use, an amplified guard signal may be applied to the superguard conductor 5 which has the effect of making the guard appear bigger. According to GB 2,374,422, this may be effective in automotive applications when the proximity sensor 50 is assembled, for example in the rear-side bumper of a car, to minimize the effect of water drips running down in rainy weather conditions across the bumper, on the signal of the sensor conductor 7.

The superguard conductor 5 comprises an electrically conductive material and, in some embodiments, one or more metals. In some embodiments, the superguard conductor 5 comprises a relatively cheap material such as an aluminium layer which may be applied to the backing 2 as an aluminum film or foil, respectively, by means of, for example, an adhesive layer such as a pressure-sensitive adhesive layer. In another embodiment the superguard conductor 5 may comprise a metal layer such as an aluminum or copper layer applied to the backing layer 2 by vacuum metal vapour deposition. Alternatively it is also possible to apply the vacuum metal vapour deposit coating layer to a carrier film comprising, e.g., a polymer layer; the carrier film bearing the metal coating layer is then attached e.g. by means of an adhesive layer to the backing layer 2. In still another embodiment the superguard conductor may be discontinuous and formed, for example, by flattened metal wires which are attached to the backing layer 2, for example, by an adhesive layer.

The superguard conductor 5, if present, may assume a variety of shapes and can be continuous or discontinuous, respectively. In automotive applications where the capacitive sensor film 50 is assembled into the rear-side bumper of a vehicle, for example, the superguard conductor 5 may advantageously assume the form of an elongated strip extending along the rear-side bumper.

The thickness of the superguard conductor 5 may vary widely depending on the method of manufacturing it. Superguard conductor layers 5 obtained by vacuum metal deposition may be as thin as 200-800 Å and, in some embodiments, 300-500 Å. When using an aluminum foil as a superguard conductor layer 5 it may have a thickness of from 1-100 μm, in some embodiments, 2-50 μm and in some embodiments, 3-30 μm.

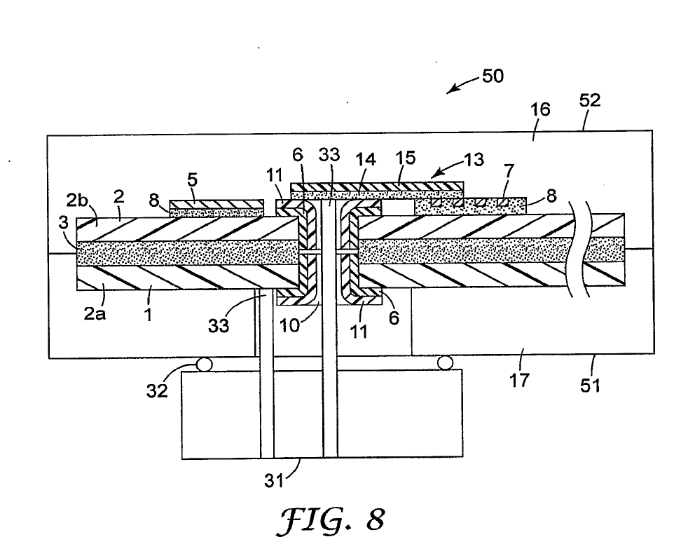

As described below, the guard conductor 1, the sensor conductor 7 and, if present, the superguard conductor 5 of the capacitive sensor film 50 of some embodiments of the present disclosure are electrically contacted from one of the major surfaces 51, 52 (FIG. 8) of the film. The rear major surface 51 of the film 50 may be formed by the exposed surface of the guard conductor or, if present, by the exposed surface of a rear protective layer 17 (see below). The front major surface 52 of the film 50 may be formed by the front major surface 2b of the backing layer 2 or the exposed surfaces of the sensor conductor 7 or the superguard conductor 5, respectively, or, if present, by the exposed surface of a front protective layer 16 (see below). With a view to establishing electrical contact with the conductors 1, 5, 7, the capacitive sensor film 50 of some embodiments of the present disclosure comprises at least one through-going hole 10 extending through the backing layer 2 to one of the major surfaces 51, 52 of the film 50. In case electrical connections are made to the capacitive sensor film 50 from its rear major surface 51, the sensor conductor 7 and, if present, the superguard conductor 5 may be contacted through such one or more through-going holes 10. Likewise, in case the film 50 is electrically contacted from its front major surface 52, the guard conductor 1 may be contacted through such one or more through-going holes 10.

The one or more through-going holes 10 may be applied by any punching or die-cutting device such as, for example, by a pneumatic or mechanical hole punch, machined die or rotating block. The cross-section of the through-going holes 10 may have any shape including, for example, a circular, ellipsoidal, rectangular or irregular shape. The cross-sectional dimension of the through-going holes 10 is not critical and is selected to allow for a reliable electrical connection while not adversely affecting the integrity of the capacitive sensor laminate. In some embodiments, the cross-sectional dimension of the through-going holes varies between 0.1 and 5 square centimeters (cm²) and, in some embodiments, between 0.5 and 2.5 cm².

The one or more through-going holes 10 may be arranged inside or outside the area of the guard conductor 1, the sensor conductor 7 and/or—if present—the superguard conductor 5. If the through-going hole 10 is arranged, for example, inside the area of the sensor conductor 7 within a capacitive sensor film 50 which is electrically contacted from its rear surface 51, such through-going holes 10 may or may not extend through the sensor conductor 7. In some embodiments, the one or more through-going holes 10 extend to the rear surface of the sensor conductor 7 but do not extend through the sensor conductor 7. In this embodiment the rear surface of the sensor conductor 7 can be easily contacted through the one or more through-going holes 10 from the rear surface 51 of the laminate. In this embodiment it is alternatively also possible that the one or more through-going holes 10 extend through the sensor conductor 7 so that the front surface of the sensor conductor 7 can be contacted through the one or more through-going holes 10 from the rear side 51 of the laminate.

Likewise, if a superguard conductor 5 is present and the capacitive sensor film 50 is contacted from its rear side 51, such contact may be made through one or more further through-going holes which may end at the rear surface of the superguard conductor 5 or extend through the superguard conductor 5, respectively. It is also possible that the sensor conductor 7 and the superguard conductor 5 are contacted through one through-going hole 10.

If the capacitive sensor film 50 is contacted from its front surface 52, the one or more through-going holes 10 may likewise extend to the front surface of the guard conductor 1 or extend through the guard conductor 1, respectively.

It is, however, also possible that the one or more through-going holes 10 are arranged outside the area of the guard conductor 1, the sensor conductor 7 and/or—if present—the superguard conductor 5.

In some embodiments, a capacitive sensor film 50 of the present disclosure which is electrically contacted from its rear side 51, the one or more through-going holes 10 are arranged outside the area of the sensor conductor 7 and/or the superguard conductor 5, if present.

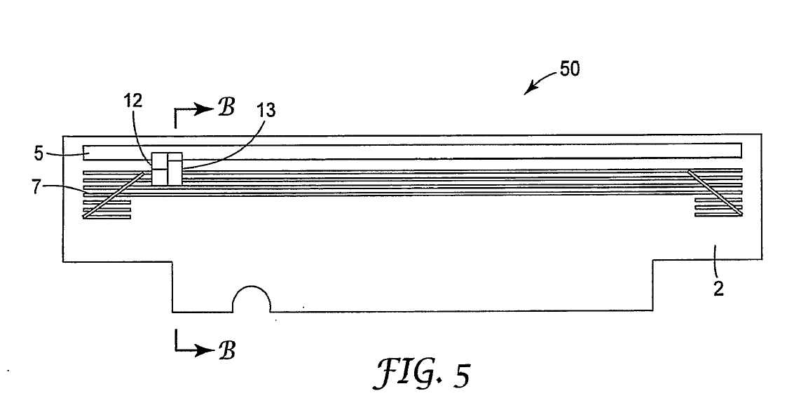

In this case, one or more auxiliary conductors 12, 13 (FIG. 5) may be provided which are electrically connected to the sensor conductor 7 and, if present, to the superguard conductor 5. The auxiliary conductors 12, 13 may be formed, for example, by electrically conductive adhesive tapes comprising a backing bearing an electrically conductive adhesive. A strip of such tape is attached via its electrically conductive adhesive layer to the sensor conductor 7, and the length of such adhesive strip is selected so that it extends into the area of the through-going hole 10. Thus, the sensor conductor 7 can be electrically connected from the rear side 51 of the capacitive sensor film 50 via such auxiliary conductive adhesive strip. If the capacitive sensor film additionally comprises a superguard conductor 5, a separate auxiliary conductor 13 which may be an electrically conductive adhesive strip may be provided and electrically connected to the superguard conductor 5. Such strip extends into the area of the through-going hole 10 without contacting the adhesive strip 12 attached to the sensor conductor 7.

The auxiliary conductors 12, 13 may also be formed by metal foils or carrier films bearing a metal coating layer obtained, e.g., by vacuum metal vapour deposition. Such conductors 12, 13 are applied so that the metal foil or the metal coating layer contacts the sensor conductor 7 and, if present, the superguard conductor 5, and they may be held in place, for example, by conventional one-sided adhesive tapes.

The backing of an electrically conductive adhesive tape which can be used as auxiliary conductor 12, 13, may include electrically conductive and non-conductive materials such as metal films or polymeric films. Conductive film tapes comprising an aluminum or copper foil backing, respectively, bearing in each case an electrically conductive pressure-sensitive adhesive, are commercially available from 3M Company, St. Paul/Minn., USA, under the trade designations “3M 1170 EMI Aluminium Foil Shielding Tape” and “3M 1181 EMI Copper Foil Shielding Tape”, respectively. An aluminum foil having a thickness of 20 μm which can be used as a conductor 12, 13 is available, for example, from Tesco Comp. under the designation “cooking foil”.

The conductor 12 may generally be formed by any material which can be attached to the sensor conductor 7 or, if present, to the superguard conductor 5 in an electrically connecting way and which is sufficiently self-supporting so that it provides a reliable electrical contact area within the area of the through-going hole 10. The conductor 12 may also be formed, for example, by an optionally flattened metal wire which is attached to the sensor conductor 7 and the superguard conductor 5 by means of an electrically conductive adhesive.

An electrically insulating film 11 is applied to fully cover the one or more through-going holes 10 on the front and/or rear side of the backing layer 2, respectively, before applying the conductors 12, 13. Such electrically insulating film comprises a backing which may be formed, for example, by any non-conductive polymeric or paper film. Useful non-conductive polymeric materials include, for example, polyolefin polymers, monoaxially oriented polypropylene (MOPP), biaxially oriented polypropylene (BOPP), simultaneously biaxially oriented polypropylene (SBOPP), polyethylene, copolymers of polypropylene and polyethylene, polyvinylchloride, copolymers having a predominant olefin monomer which may optionally be chlorinated or fluorinated, polyester polymers, polycarbonate polymers, polymethacrylate polymers, cellulose acetate, polyester (e.g. biaxially oriented polyethylene terephthalate), vinyl acetates, and combinations thereof. The electrically insulating film 11 bears an adhesive layer 6 and, in particular, a pressure-sensitive adhesive layer on one of its major surfaces through which it is attached to the front and/or rear side of the capacitive sensor film 50. The electrically insulating film 11 is applied to the front major surface of the backing film 2 and/or to the exposed surface of the guard conductor 1 so that it fully covers in each case the through-going hole 10. Then, holes are punched through the one or more electrically insulating films so that the through-going hole 10 is restored which now additionally extends through the insulating films. The cross-sectional extension and/or shape of the holes punched into the electrically insulating films are selected so that the hole punched through the insulating film is smaller than the through-going hole punched originally. The edges of the electrically insulating films 11 extending into the area of the through-going hole 10, bond to the inner wall of the through-going hole 10 thereby electrically insulating the guard conductor 1 from the sensor conductor 7 and, if present, from the superguard conductor 5. In some embodiments, the length of the edges of the electrically insulating films 11 extending into the area of the through-going hole 10 is selected so that the inner wall of the through-going hole is essentially fully covered by the electrically insulating films 11. This specific design reliably insulates the guard conductor 1 from the sensor conductor 7 and, optionally, the superguard conductor 5 and additionally reinforces the area of the through-going hole 10. Electrically insulating films 11 may be applied both to the front major surface 2b of the backing film 2 and to the exposed surface of the guard conductor 1 of the through-going hole 10.

The above exemplary embodiment has been described for the case that the capacitive sensor film 50 is contacted from its rear major surface 51.

It is, however, also possible that the capacitive sensor film 50 is contacted from its front major surface 52. In such case the one or more through-going holes 10 will extend from the front major surface 52 to the front surface of the guard conductor 1 or through the guard conductor to its rear surface, respectively. If the guard conductor does not fully cover the rear major surface 2a of the backing 2 and the one or more through-going holes are arranged outside the area of the guard conductor 1, one or more auxiliary conductors 12, 13 and, if desirable, one or more insulating films 11 are used as was described above to allow for an easy and reliable connection.

In some applications it is desirable to seal the capacitive sensor film 50 between protective films 16, 17 to protect the capacitive sensor film 50 against environmental impacts such as water or moisture, to electrically insulate the film 50 and/or to render it more easily handleable. Such protective films may be selected from the group of polymeric films, layers and laminates. Useful polymers include, for example, polyolefin polymers, monoaxially oriented polypropylene (MOPP), biaxially oriented polypropylene (BOPP), simultaneously biaxially oriented polypropylene (SBOPP), polyethylene, copolymers of polypropylene and polyethylene, polyester polymers, polycarbonate polymers, polymethacrylate polymers, cellulose acetate, polyester (e.g. biaxially oriented polyethylene terephthalate), vinyl acetates, and combinations thereof.

The protective polymer films may be applied to the front major surface 2a of the backing layer bearing the sensor conductor 7 and, optionally, the superguard conductor 5 and to the guard conductor 1 on the back major surface 2a of the backing 2 by adhesive means including, for example, hot-melt adhesives and pressure-sensitive adhesives. In another embodiment, the protective film may also be heat-laminated onto the front major surface 2b of the backing layer 2 and the guard conductor 1, respectively. In some embodiments, the length and width of the protective films 16, 17 preferably exceed the length and width of the backing film 2 and/or the guard conductor 1 to provide an edge sealing to the capacitive sensor film 50 to protect, in particular, the edges of the guard conductor against corrosion. In some embodiments, the length and width of the protective films 16, 17 is preferably selected to provide an edge sealing border with a width of 1-50 millimeters (mm), in some embodiments, of 1-40 mm and, in some embodiments, of 2-20 mm. In some embodiments, in particular in automotive applications, to include cuts and darts into the capacitive sensor film 50 so that the film can be better fitted to three-dimensional curvatures such as, for example, to the bumper inner skin. This allows the film 50 to lay essentially flat to the bumper inner skin without forming undesirable creases to an unacceptable degree. This applies to both edge-sealed films 50 comprise at least one protective film 16, 17 and to non-edge-sealed films 50.

The one or more through-going holes 10 may be punched into the protective film 16, 17 on the major surface of the capacitive sensor film 50 from which the capacitive sensor film 50 is contacted thereby extending the through-going holes to such surface. In case the capacitive sensor film 50 is contacted from its rear major surface 51 a further hole may be punched into the protective film 17 to allow for contacting the guard conductor 1. Likewise, in case the capacitive sensor film 50 is contacted from its front major surface 52, one or more additional holes may be punched into the protective layer 16 to allow for contacting the sensor conductor 7 and, optionally, the superguard conductor 5 whereas the guard conductor 1 is contacted via one or more through-going holes 10.

Alternatively, one or more holes can be punched at appropriate locations into the protective film 16, 17 prior to lamination so that such pre-punched holes extend the through-going hole or holes 10 to the respective major surface of the capacitive sensor film 50 and/or provide access to the desired conductors 1, 7 and/or 5.

Connecting cables or strips 33 are supplied through the one or more through-going holes 10 or through the additional holes which may be present to contact the guard conductor 1, the sensor conductor 7 and, optionally, the superguard conductor 5 and/or any auxiliary conductors 12, 13 which may be attached to conductors 1, 7 5. If the capacitive sensor film 50 is contacted, for example, from its rear major surface 51, connection strips 33 are supplied from the rear side 51 of the capacitive sensor film 50 through the one or more through-going holes 10 and pressed against the sensor conductor 7, the superguard conductor 5 and/or the auxiliary conductors 12, 13, respectively to establish electrical contact. Pressure can be applied, for example, via spring loaded pads which continuously press on the connection areas between the connectors and the sensor conductor 7, the superguard conductor 5 and/or the auxiliary conductors 12, 13, respectively.

In some embodiments, the one or more through-going holes 10 may be filled with a conductive ink such as a silver ink which is subsequently solidified by evaporative drying or curing. The through-going hole 10 may also be filled, for example, with a precursor of a silver epoxy adhesive which is thermally cured upon insertion into the one or more through-going holes 10. In these constructions the connecting strips 33 do not need to be supplied through the through-going holes 10 but can be applied, for example, at the respective major surface 51, 52 of the capacitive sensor film 50. Establishing of electrical contact between the connectors and the sensor conductor 7, the superguard conductor 5 and/or the conductors 12, 13 is thus facilitated, and the resulting connection is more reliable and mechanically stable.

The capacitive sensor film 50 of some embodiments of the present disclosure can thus easily and reliably be electrically contacted from one of its major surfaces 51, 52.

Contacting the capacitive sensor film 50 from its rear major surface 51 is particularly preferred in automotive applications.

It is usually desirable to integrate the connectors contacting the guard conductor 1, the sensor conductor 7 and, optionally, the superguard conductor 5 and/or the conductors 12, 13 in a socket body 31 (FIG. 8) which may be applied to the capacitive sensor film 50 to allow for a standardized connection. In some embodiments, a complete hermetic seal is preferably formed between the periphery of the socket body 31 and the surface of the capacitive sensor film 50, thus preventing water, air or dust ingress into the connection area. In one embodiment, the socket body 31 comprises sealing means such as sealing O rings 32 around its periphery contacting the capacitive sensor film 50. The socket body 31 is applied to the capacitive sensor film 50 so that the sealing O rings are pressurized and form the required hermetic seal.

The capacitive sensor film 50 of some embodiments of the present disclosure may be advantageously used in automotive applications for sensing the proximity of a car to other objects where it can be introduced, for example, in the rear and front bumper. The capacitive sensor film 50 can be cut into the required shape by any die-cutting, punching or laser cutting means, for example. Due to its flexibility it can be easily processed and bent into conformity with the bumper shape, if required. It is particular advantageous that the capacitive sensor film 50 can be easily electronically connected from its rear side which does not only facilitate assembling at the OEM (original equipment manufacturer) site but also allows, for example, for an easy replacement of such capacitive sensor film 50 if the bumper incorporating it is damaged in an accident.

The capacitive sensor films 50 of some embodiments of the present disclosure can be easily installed and they are flexible so that they can be applied to shaped substrates having, for example, curved surfaces. It is particularly advantageous that the capacitive sensor films 50 can be electrically contacted in an easy and reliable way. In view of these advantages the capacitive sensor films 50 of the present disclosure are especially suited for use in the automotive industry.

Devices which are suitable for measuring and processing signals of the sensor conductor 7 have been disclosed, for example, in WO 02/19,524 and are not further described here.

It will be understood that the particular configurations shown in the drawings for the sensor and guard conductors and the optional superguard conductor are for the purposes of illustration only and are not an essential feature of the invention. The proximity sensors described herein with reference to the drawings are particularly appropriate for use on vehicle bumpers but the manner in which electrical connection is made from one side of the sensor film to the sensor and guard conductors (and, when present, the superguard conductor) is applicable to sensor films intended for use in other applications and to sensor films with differently-configured conductors including, for example, sensor films with a sensor conductor of serpentine or spiral form or with two interdigitated sensor conductors, or with a multiplicity of guard conductors.

In one method of manufacturing a capacitive sensor film 50 of the present disclosure which may be contacted from one of its major surfaces 51, 52, an aluminum film laminate comprising the backing layer 2 bearing an aluminum layer which forms the guard conductor 1, is provided first. The sensor conductor 7 and the superguard conductor 5, if present, may be metal films or foils which are applied to the other major surface of the backing layer 2 which is opposite to the guard layer 1, for example, by adhesive means. Alternatively, the sensor conductor 7 and the superguard conductor 5, if present, may also be applied by vacuum metal vapour coating.

Then the one or more through-going holes 10 are applied to the backing layer 2. If the capacitive sensor film 50 is to be contacted, for example, from its rear major surface 51 and if the one or more through-going holes are to extend in the area of the sensor conductor 7 and, optionally, the superguard conductor 5, such through-going holes 10 may be punched in from the rear major surface 51 so that they extend to the rear surface of the conductors 7, 5 facing the backing layer 2. Alternatively the through-going holes 10 may be punched into the backing layer 2 and the guard conductor 1 first, and the sensor conductor 7 and, if present, the superguard conductor 5 are applied subsequently. In another embodiment the one or more through-going holes 10 may extend through the sensor conductor 7 and, if present, the superguard conductor 5.

If the capacitive sensor film 50 is to be contacted, for example, from its rear major surface 51 but if the through-going holes 10 are applied outside of the area of the sensor conductor 7 and the superguard conductor 5, auxiliary conductors 12, 13 may be applied so that they are electrically connected to the sensor conductor 7 and, if present, to the superguard conductor 5. The auxiliary conductors 12, 13 extend into the area of the one or more through-goings holes 10 and can be contacted from the rear major surface 51 of the laminate.

If the capacitive sensor film 50 is to be contacted from its front major surface 52, one or more through-going holes are applied analogously to the embodiments described above to allow for contacting the guard conductor 1. The one or more through-going holes typically extend in the area of the guard conductor 1 which generally covers at least the major part of the rear major surface 2a of the backing layer 2. The through-going holes 10 may extend to the front surface of the guard conductor 1 facing the backing layer 2, or they may also extend through the guard conductor 1. In the latter case auxiliary conductors 12, 13 may be used to facilitate providing of electrical connections.

In each case, following the formation of a through-going hole 10, an insulating film 11 is applied over the hole and a smaller hole is then punched in the film so that the surrounding edges of the film extend into, and cover the wall of, the original hole 10 to insulate the guard conductor 1 from the sensor conductor 7 (or, when present, the superguard conductor 5). In some embodiments, the turned-in portion(s) of the films(s) 11 preferably cover the entire wall of the hole 10 but may only cover a portion thereof, sufficient to prevent the inadvertent electrical connection, via the hole 10, of the guard conductor to the sensor or superguard conductor.

In some embodiments, protective layers 16, 17 are sealed to the capacitive sensor film 50, for example, by heat lamination or by means of a hot melt adhesive. One or more holes to be arranged above the one or more through-going holes 10 and/or in case the film 50 is contacted, for example, from its rear major surface, above the guard conductor 1 may be punched into the protective films 16, 17 prior to applying them.

Alternatively, such hole or holes may be applied subsequently to sealing the protective films 16, 17 to the capacitive sensor film 50.

The capacitive sensor film 50 may be manufactured continuously. In such case the capacitive sensor film 50 is cut from the continuous web.

The capacitive sensor film 50 is trimmed into the required shape, for example, by die-cutting, laser cutting or a V knife on an XY table cutter. Then the electrical contact is provided from one of the major surfaces 51, 52 of the film through the one or more through-going holes 10, for example, by means of pressure contact. Contacting may be facilitated by filling the through-going holes 10 with a conductive fluid, such as, for example, a silver ink or a silver epoxy adhesive which may be subsequently cured or heat-dried. If the capacitive sensor film 50 is electrically connected from its rear major surface 51, contact can be made through the through-going holes 10 to the sensor conductor 7 and, optionally, the superguard conductor 5. The guard conductor 1 can be contacted in this embodiment, for example, by a further hole punched into the rear protective layer 17.

The protective films 16, 17 are usually larger than the backing layer 2 so that the protective films 16, 17 provide for an edge sealing.

These methods of manufacturing are highly advantageous because they can be operated continuously or semi-continuously, and they can also be included in the manufacturing lines of automobiles, for example.

### DETAILED DESCRIPTION OF THE FIGURES

The following figures are schematic and are not drawn to scale.

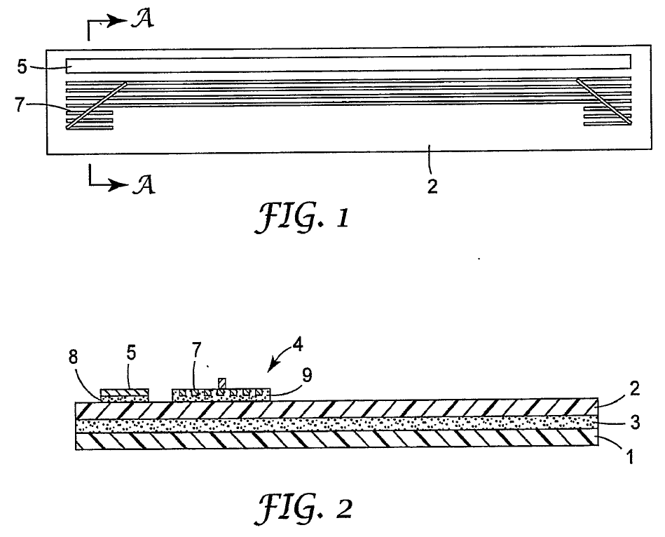

FIG. 1 shows a top view of a precursor of one embodiment of the capacitive sensor film 50 of the present disclosure comprising a backing layer 2 bearing a sensor conductor 7 arranged in the sensor area 4 and a superguard conductor 5. The sensor conductor 7 exhibits a discontinuous design and is composed of several optionally flattened metal wires extending in parallel to the long side of the backing layer 2, i.e. in a longitudinal direction. At both ends the sensor conductor 7 comprises additional shorter pieces of such wire to provide lobe type end regions in order to increase the sensitivity of the sensor conductor 7 at its end regions. The different wires of the sensor conductor 7 are connected at both end regions by two wires extending each transversely inclined to the direction of the long side of the backing layer 2. The superguard conductor S is formed by a thin metal strip extending in parallel to the long side of the backing layer 2.

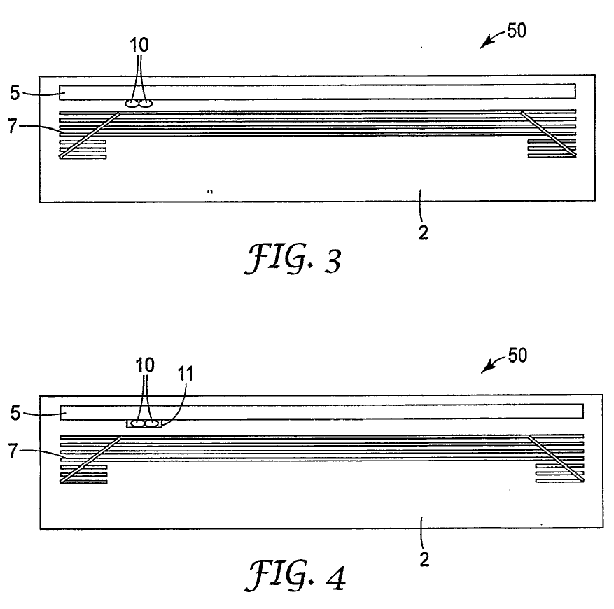

FIG. 2 is a cross-sectional view of the precursor film of FIG. 1 along the line A-A indicated in FIG. 1. The guard layer 1 extends all along the width of the backing layer 2 and is attached to it by means of the adhesive layer 3. The superguard conductor 5 and the wires forming the sensors conductor 7 are attached by the adhesive layers 8, 9 to the front major surface of the backing layer 2 which is opposite to the guard layer 1. The metal wires or metal strips of the sensor conductor 7 are embedded into adhesive layer 9 but it is also possible, for example, that the metal wires or metal strips are each attached by small adhesive spots. The small square residing on top of the wires or strips embedded in the adhesive layer corresponds to the transversely inclined wire or strip connecting the embedded wires or strips.

FIG. 3 is a top view of a capacitive sensor film 50 obtained from the precursor of FIG. 1 by applying two through-going holes 10 in the area between the superguard conductor 5 and the sensor conductor 7.

FIG. 4 is a top view of the capacitive sensor film 50 of FIG. 3 where an electrically insulating film 11 has been applied to the front surface of the backing layer 2 so that it covers the two through-going holes 10 initially created. Subsequently, holes have been punched into the insulating film 11 to restore the through-going hole 10. The holes punched into the insulating film 11 are smaller than the through-holes 10 created initially.

FIG. 5 is a top view of the capacitive sensor film 50 of FIGS. 3 and 4 where auxiliary conductors 12, 13 have been applied extending from the superguard conductor 5 and the sensor conductor 7, respectively, into the area of the respective through-going hole 10. The capacitive sensor film has already been cut into the shape required for its insertion into a car bumper.

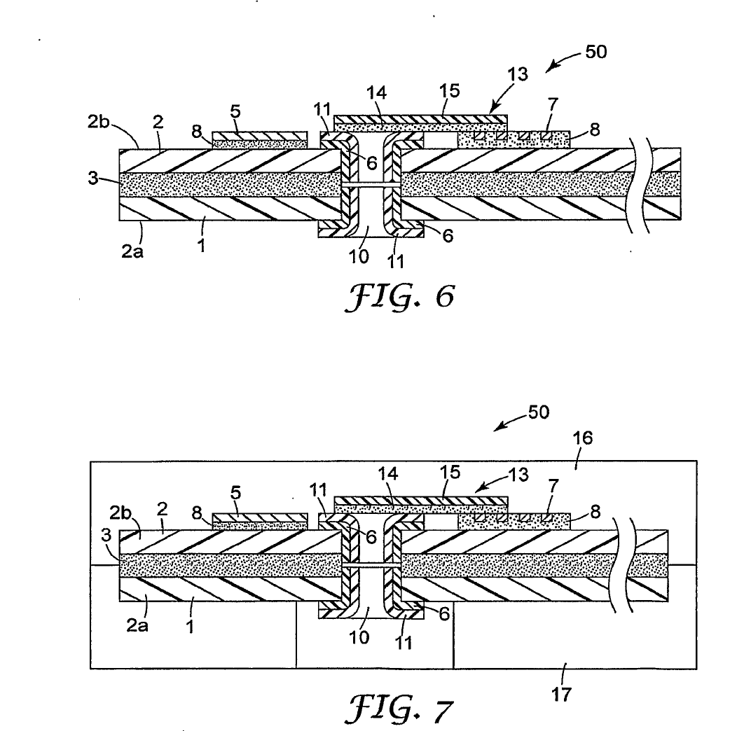

FIG. 6 is a cross-sectional view of the capacitive sensor film 50 of FIG. 5 along the line B-B indicated in FIG. 5. It can be seen that the insulating film 11 has been applied to both the front and rear side of the capacitive sensor film 50, and that holes have been punched into such insulating film 11 which are smaller than the through-going hole 10 initially created, causing the surrounding edges of the film to extend into, and cover the wall of, the hole 10. The insulating film 11 comprises an adhesive layer 6 which holds the insulating film 11 in place. The auxiliary conductor 13 comprising a backing 15 and an electrically conducting adhesive layer 14 is attached to the sensor conductor 7 and extends over the through-going hole 10 to the insulating film 11 on the opposite side of the hole. It can be seen that the sensor conductor 7 is electrically connectable via the through-going hole 10 from the rear side of the capacitive sensor film 50 but that electrical contact with the guard conductor 1 is prevented by the turned-in portions of the insulating films 11.

FIG. 7 and FIG. 8 are cross-sectionals view of the capacitive sensor film 50 of FIG. 5 along the line B-B of FIG. 5 additionally comprising protective layers 16, 17 sealed to both the front and rear major surface 2a, 2b of the backing 2 by means of a hot-melt adhesive 18 (not shown). A hole has been cut into the protective layer 17 applied to the rear major surface 2a of the backing layer 2 in order to extend the through-going hole 10 to the rear surface of the protective layer 17. The width of the through-going hole 10 in the protective layer 17 exceeds the width of the through-going hole 10 in the backing layer so that the connecting strips 33 contacting the guard conductor 1, the sensor conductor 7 and the superguard conductor 5 can be integrated into a socket housing 31. This is shown in FIG. 8 which is a cross-sectional view of the capacitive sensor film 50 of FIG. 5 along line B-B wherein the capacitive sensor film additionally comprises a socket 31 which is applied to the rear major surface 51 of the capacitive sensor film 50. The guard conductor 1 and the connector 13 (which is electrically connected to the sensor conductor 7) are connected to connecting strips 33 which are fed into the socket 31. The socket 31 comprises O sealing rings 32 which are pressurized and form a hermetic seal. A gasket of adhesive may be used instead of the O sealing ring.

Embodiments of the present disclosure are further illustrated in the following non-limiting Examples.

### EXAMPLES

### Example 1

A conventional aluminum foil (thickness 20 μm) which is available from Tesco Comp., UK, as a cooking foil was laminated to a 100 μm polyethyleneterephthalate (PET) film bearing a 25 μm ethylenevinylacetate (EVA) adhesive layer. The PET film bearing the adhesive layer was available from GBC, UK. The lamination was performed at a temperature of about 110° C. using an office type laminator. The aluminum layer acted as the guard layer.

On the major side of the PET film opposite to the aluminum guard layer a 12 mm wide aluminum foil tape available from 3M Company under the designation “3M Aluminum Foil Tape 425” was applied along the whole length of the PET film. This aluminum strip tape acted as a superguard layer. Then a double-sided adhesive tape (available from 3M Company under the designation 9512 was applied to the major surface of the backing layer opposite to the guard layer and next to the superguard layer. A sequence of flattened copper wires (tin plated copper wires, 50 μm thick and 0.5 mm wide, available from Chaplin Bros, Birmingham, UK) which extended along the length of the PET film was applied to the exposed surface of the double-sided adhesive tape. The wires were each parallel to the long side of the PET film (I.e. extended in a longitudinal direction) and spaced 5 mm apart. The wires arranged in parallel in such longitudinal direction were electrically connected to each other by another flattened copper wire extending in a transversely inclined direction with respect to the longitudinal direction. This discontinuous arrangement of flattened wires formed the sensor conductor.

Then, connector holes were punched in the area of the backing layer between the guard conductor and the superguard conductor through the backing layer and the guard conductor using engineer's hole punch.

Then a polyester film pressure sensitive adhesive tape (8417, available from 3M) was applied to the front major surface of the backing layer and the exposed surface of the guard layer, respectively, so that the through-going hole was covered on the front and rear side of the backing layer. Then a hole, smaller than the original one was cut through the polyester films, in order to obtain an isolating ring. Aluminium foil tape (Al tape 1170, available from 3M) and copper foil tape (Copper foil tape: Cu tape 1181, available from 3M) were applied. A strip of a laminate formed of aluminium foil conductive adhesive tape 1170, 5 mm wide and a 25 mm wide piece of polyester tape 8417 was electrically connected to the sensor conductor so that the opposite end extended into the area of one of the through-going hole. A strip of a laminate of copper foil conductive adhesive tape 1181, 5 mm wide on a 25 mm wide piece of polyester tape 8417 was electrically connected to the superguard conductor so that the opposite end extended into the area of the other through-going hole. The laminate strips were applied such that there was a 5 mm gap between the two conductive tape strips.

The capacitive sensor film thus obtained was then laminated between two pieces of heat seal protective polyester film (50μ PET film with 25 μl EVA heat seal adhesive, available from GBC, UK). Appropriate holes were cut into the protective polyester film applied to those areas of the rear side of the capacitive sensor film covering the through-going holes.

Finally, a conductive silver ink obtainable from Sun Chemicals was filled into the through-going holes and dried. Then a socket body was applied. The capacitive sensor film was then trimmed to shape and the connector applied to make the electrical contacts.

### Example 2

Example 1 was repeated using a 6.35 μm thick aluminum foil obtainable from Alcan, UK, which was laminated to a 80 μm thick filled polypropylene film obtainable from RKW, Sweden, under the trade designation FPO bearing a 20 μm ethylene vinylacetate adhesive layer. The FPO film is a blown film comprising calcium carbonate and talc particles which are bound in a polypropylene matrix. The aluminum foil was laminated to the adhesive layer on the FPO film at a temperature of 90° C. using an office type laminator.

Then the sensor conductor and the superguard conductor were applied and the through-going holes were provided, covered with 8417 tape and punched through to provide holes smaller than the original through-going hole as was described in Example 1.

Then a strip of a laminate formed of a 5 mm wide strip of an aluminum foil (20 μm thick, available from Tesco Comp., UK, as cooking foil) and of a 25 mm wide strip of polyester tape 8417 were electrically connected to each of the sensor conductor and the superguard conductor, respectively, so that the opposite end extended into the area of one of the through-going holes each. The other details were selected as described in Example 1.

The resulting capacitive sensor film was laminated between two heat and protective FPO films (60 μm thick with a 25 μm EVA layer) as was described in Example 1. Connections were made by pressure contact by forming a cross cut through each connection area, pushing through a small machine screw, applying a washer and a nut to the guard conductor side and tightening down to form an electrical contact with the sensor conductor and the superguard conductors, respectively.

### Example 3

Example 1 was repeated but an aluminized film comprising a 12 μm PET film bearing a 300-500 Å aluminium vapour coat (available from Amcor, UK) laminated to an FPO film as in Example 2 was used instead of the laminate of the Al foil and the PET film.

1-20. (canceled)

21. A capacitive sensor film for mounting to a body, comprising a dielectric backing layer having a rear major surface facing, in use, the body and, on the other side, a front major surface, said rear major surface bearing a guard conductor and said front major surface bearing a sensor conductor, and at least one through-going hole defined by an inner wall extending through the backing layer, wherein the inner wall of the through-going hole is covered, at least partly, by an electrically-insulating film.

22. Capacitive sensor film according to claim 21 wherein said front major surface additionally bears a superguard conductor.

23. Capacitive sensor film according to claim 21, in which the electrically-insulating film extends into the through-going hole from at least one of the major surfaces of the backing layer.

24. Capacitive sensor film according to claim 21, in which the electrically-insulating film is adhered to the inner wall of the through-going hole.

25. Capacitive sensor film according to claim 24, in which the electrically-insulating film is also adhered to a major surface of the backing layer around the through-going hole.

26. Capacitive sensor film according to claim 25, in which the electrically-insulating film is adhered to the wall of the through-going hole and the major surface of the backing layer by an adhesive.

27. Capacitive sensor film according to claim 25, in which a hole formed in the electrically-insulating film in alignment with the through-going hole (10), and a portion of the electrically-insulating film surrounding the hole is adhered to the inner wall of the through-going hole.

28. Capacitive sensor film according to claim 21, wherein the through-going hole is arranged so that it does not extend through the sensor conductor.

29. Capacitive sensor film according to claim 28, wherein an auxiliary connector is electrically connected to the sensor conductor and extends essentially parallel to the front major surface of the backing layer at least partly over the through-going hole.

30. Capacitive sensor film according to claim 21, wherein the guard conductor, the sensor conductor and, if present, the superguard conductor are provided with electrical connectors so that such connectors can be fed into a socket which is arranged on one side of the film, wherein one of the electrical connectors extends through the said through-going hole.

31. Capacitive sensor film according to claim 21, in which the through-going hole is filled with an electrically-conductive material.

32. Capacitive sensor film according to claim 21 comprising one or more protective layers applied to the rear major surface of the backing layer and/or on the front surface of the backing layer.

33. Capacitive sensor film according to claim 32, wherein an extension of the protective layers exceeds an extension of the backing layer in both the length and the width direction of the sensor film and the protective layers are laminated against each other around the edge of the sensor film thereby forming an edge sealing.

34. Capacity sensor film according to claim 21, wherein the sensor conductor is a metal film bonded to the front surface of the backing layer with an adhesive layer or is applied to the front surface of the backing layer by metal vapour coating.

35. Capacity sensor film according to claim 21, wherein the sensor conductor is an electrically conductive film or pattern comprising a conductive ink.

36. Capacitive sensor film according to claim 21 wherein the sensor conductor forms a continuous or discontinuous metal area or areas whereby the discontinuous areas are electrically connected.

37. Capacitive sensor film according to claim 21 wherein the guard conductor is a metal film bonded to the rear surface of the backing layer with an adhesive layer or is applied to the rear surface of the backing layer by metal vapour coating.

38. Capacitive sensor film according to claim 21 wherein the area of the guard conductor is selected to shield the sensor conductor and, if present, the superguard conductor.

39. Method of manufacturing a capacitive sensor film comprising
(i) providing a backing layer comprising a rear major surface and a front major surface,
(ii) applying a guard conductor to the rear major surface of the backing layer,
(iii) applying a sensor conductor to the front major surface of the backing layer, and
(iv) providing one or more through-going hole or holes extending through the backing layer so that the guard conductor, the sensor conductor and optionally the superguard conductor can be electrically contacted from one major surface of the laminate.

40. The method of claim 39, further comprising applying an electrically-insulating film to a major surface of the backing layer, over a through-going hole, forming a hole in the electrically-insulating film in alignment with the through-going hole and pushing the surrounding portion of the electrically-insulating film into the through-going hole to cover at least part of the wall thereof.
